(19) United States
(12) Patent Application Publication
(10) Pub. No.: US 2025/0300012 A1
(43) Pub. Date: Sep. 25, 2025

(54) INTERCONNECT STRUCTURE AND METHODS THEREOF

(71) Applicant: Taiwan Semiconductor Manufacturing Company, Ltd., Hsinchu (TW)

(72) Inventors: Yun-Chi Chiang, Hsinchu City (TW); Meng-Pei Lu, Hsinchu City (TW); Ching-Fu Yeh, Hsinchu City (TW); Cian-Yu Chen, Taichung City (TW); Chin-Lung Chung, Taoyuan City (TW); Shin-Yi Yang, New Taipei City (TW)

(21) Appl. No.: 18/609,456

(22) Filed: Mar. 19, 2024

(51) Int. Cl. H01L 21/768; H01L 23/522; H01L 23/532

(52) U.S. Cl. CPC H01L 21/76846; H01L 21/76802; H01L 21/76856; H01L 21/76877; H01L 23/5226; H01L 23/53238

(57) ABSTRACT

A method and structure for forming an interconnect layer includes forming a first metal interconnect layer, depositing a dielectric layer over the first metal interconnect layer, patterning the dielectric layer to form an opening that exposes the first metal interconnect layer, forming a doped barrier layer or a hybrid barrier layer along sidewalls and a bottom surface of the opening, and depositing a metal layer over the doped barrier layer or the hybrid barrier layer.

### BACKGROUND

The electronics industry has experienced an ever-increasing demand for smaller and faster semiconductor devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As merely one example, the formation of high-quality interconnects, including reliable metal lines and vias, has proved challenging. In particular, with the continued scaling of IC dimensions, and the corresponding reduction of layer thicknesses (e.g., metal, dielectric, and barrier layer thicknesses), ramping of the resistance of metal interconnect layers has become a critical issue. For instance, in existing metallization techniques, a back-end-of-line (BEOL) interconnect structure may include a barrier layer, a liner layer, and a metal interconnect layer (e.g., such as a copper layer), where the barrier layer and the liner layer interpose the metal interconnect layer and a surrounding low-K dielectric layer. As IC dimensions are scaled, the barrier and liner layers occupy a greater volume ratio of the BEOL interconnect structure, as compared to the metal interconnect layer, thereby causing the resistance of the metal interconnect layer to increase.

Thus, existing techniques have not proved entirely satisfactory in all respects.

### BRIEF DESCRIPTION OF THE DRAWINGS

Aspects of the present disclosure are best understood from the following detailed description when they are read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method of forming an interconnect layer, in accordance with some embodiments;

FIGS. 2, 3, 4, and 5 provide cross-sectional views of a device at intermediate stages of fabrication and processed in accordance with the method of FIG. 1;

FIGS. 6A, 6B, 6C, and 6D provide examples of different interconnect structure schemes, in accordance with some embodiments;

FIGS. 6E, 6F, 6G, 6H, and 6I illustrate examples of various embodiments of a doped barrier layer, in accordance with some embodiments;

FIG. 6J illustrates an example of an embodiment of a hybrid barrier layer, in accordance with some embodiments;

FIG. 7 illustrates a portion of a multi-level interconnect network, in accordance with some embodiments;

FIG. 8 is a perspective view of an MOS transistor according to some embodiments;

FIG. 9 is perspective view of an embodiment of a FinFET device according to one or more aspects of the present disclosure; and

FIG. 10 is a cross-sectional view of a GAA device according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm.

It is also noted that the present disclosure presents embodiments in the form of interconnect structures employed within a back-end-of-line (BEOL) process where a multi-level metal interconnect network is fabricated. In some embodiments, the interconnect structures described herein may be employed within a local interconnect structure, an intermediate interconnect structure, and/or a global interconnect structure. As used herein, the term “local interconnect” is used to describe the lowest level of metal interconnects and are differentiated from intermediate and/or global interconnects. Local interconnects span relatively short distances and are sometimes used, for example, to electrically connect a source, drain, body, and/or gate of a given device, or those of nearby devices. Additionally, local interconnects may be used to facilitate a vertical connection of one or more devices to an overlying metallization layer (e.g., to an intermediate interconnect layer), for example, through one or more vias. Interconnects (e.g., including local, intermediate, or global interconnects), in general, may be formed as part of a BEOL fabrication processes and include a multi-level network of metal wiring. One of ordinary skill may recognize other embodiments of interconnect structures that may benefit from aspects of the present disclosure.

In addition, and in some embodiments, the techniques described herein and including the disclosed interconnect structures may be employed within other semiconductor structures, circuits, and devices such as planar bulk metal-oxide-semiconductor field-effect transistors (MOSFETs), complementary MOS (CMOS) devices, multi-gate transistors (planar or vertical) such as FinFET devices, gate-all-around (GAA) devices, Omega-gate (Ω-gate) devices, or Pi-gate (II-gate) devices, as well as strained-semiconductor devices, silicon-on-insulator (SOI) devices, partially-depleted SOI devices, fully-depleted SOI devices, memory devices such as flash memory (e.g., NAND or NOR flash memory), logic circuits, or other structures, circuits, or devices. One of ordinary skill may recognize other embodiments of semiconductor structures, circuits, or devices that may benefit from aspects of the present disclosure. Moreover, any of a plurality of IC circuits and/or devices may be connected by interconnects formed during a BEOL process.

With the aggressive scaling and ever-increasing complexity of advanced semiconductor devices and circuits, the formation of high-quality interconnects, including reliable metal lines and vias, has proved challenging. In particular, with the continued scaling of IC dimensions, and the corresponding reduction of layer thicknesses (e.g., metal, dielectric, and barrier layer thicknesses), ramping of the resistance of metal interconnect layers has become a critical issue. For instance, in existing metallization techniques, a back-end-of-line (BEOL) interconnect structure may include a barrier layer, a liner layer, and a metal interconnect layer (e.g., such as a copper layer), where the barrier layer and the liner layer interpose the metal interconnect layer and a surrounding low-K dielectric layer. As IC dimensions are scaled, the barrier and liner layers occupy a greater volume ratio of the BEOL interconnect structure, as compared to the metal interconnect layer, thereby causing the resistance of the metal interconnect layer to increase. Thus, existing methods have not been entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include an interconnect structure, and related methods, that effectively serve to overcome various shortcomings of existing methods. In particular, a variety of schemes are provided for implementation of the barrier layer and/or liner layer to effectively reduce the resistance of the interconnect structure, including reducing the resistance of the metal interconnect layer. For instance, the barrier layer of the interconnect structure may be doped (e.g., using a Co-based material, a Ru-based material, a Ta-based material, an alloy, and/or other suitable metal or compound) to form a doped barrier layer. In some cases, an in-situ treatment process (e.g., during or after formation of the barrier layer) and/or a post-treatment process may be performed to the barrier layer as part of, or independent from, the doping process. In various embodiments, a liner layer may optionally be formed over the doped barrier layer prior to formation of the metal interconnect layer (e.g., such as a copper layer). Alternatively, in some embodiments, the interconnect structure may include a hybrid barrier layer composed of metal alloys and/or compounds. In some cases, a post treatment process may also be optionally performed to the hybrid barrier layer. In some embodiments, a liner layer may optionally be formed over the hybrid barrier layer prior to formation of the metal interconnect layer. Thus, in general and with respect to implementation of the barrier layers and liner layers in the interconnect structures disclosed herein, at least four different schemes are provided: (i) doped barrier layer with a liner layer; (ii) doped barrier layer without a liner layer; (iii) hybrid barrier layer with a liner layer; and (iv) hybrid barrier layer without a liner layer.

Regardless of the particular implementation (or scheme), embodiments of the present disclosure provide for reduced resistance of the interconnect structure. For example, in various embodiments, the volume ratio of the interconnect structure occupied by the barrier/liner layers is reduced by a reduction of the thickness of the barrier and/or liner layers. As such, the volume ratio of the metal interconnect layer (e.g., such as copper) is correspondingly increased, thereby reducing the resistance of the metal interconnect layer. In some cases, the doping of the barrier layer and/or the use of the hybrid barrier layer itself provides for the reduced resistance of the interconnect structure. In addition, a lower contact resistance to a bottom layer of the interconnect structure is provided. The various embodiments disclosed herein may be applicable to any of local, intermediate, or global interconnects of a multi-level interconnect network formed as part of a BEOL process. Further, the various embodiments disclosed herein may be applicable to dual-damascene and/or single-damascene processes and structures. It is also noted that in some examples, any of the different schemes disclosed herein may be implemented within any given interconnect layer of the multi-level interconnect network. Additional details of embodiments of the present disclosure are provided below, and additional benefits and/or other advantages will become apparent to those skilled in the art having benefit of the present disclosure.

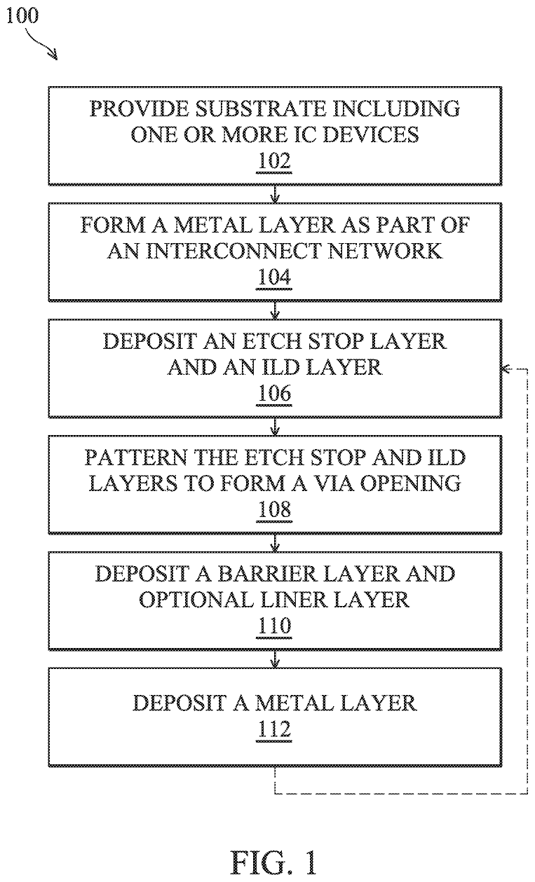

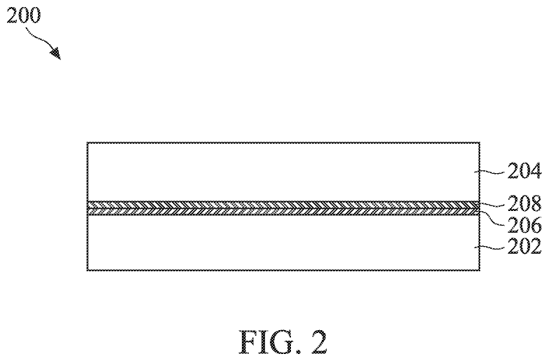

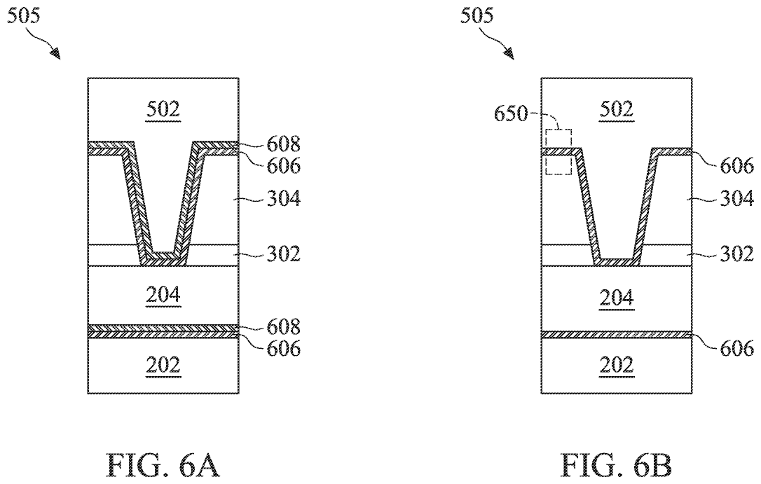

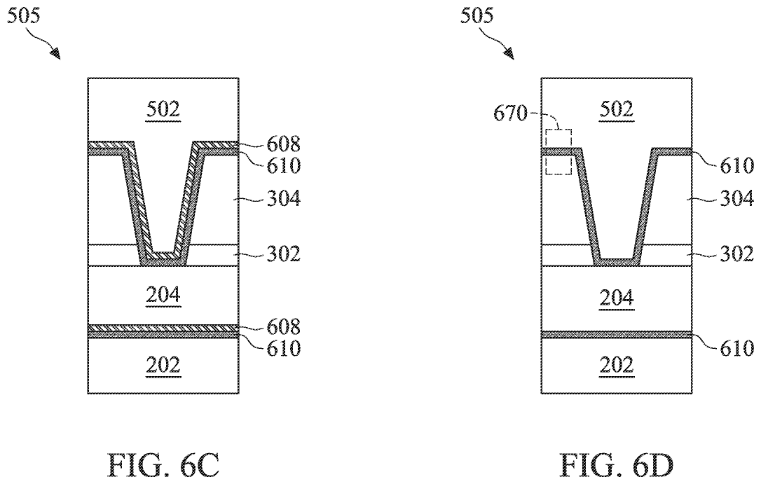

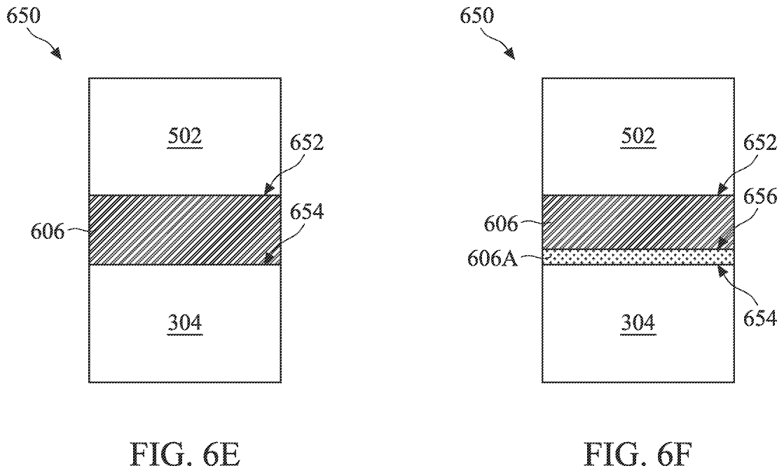

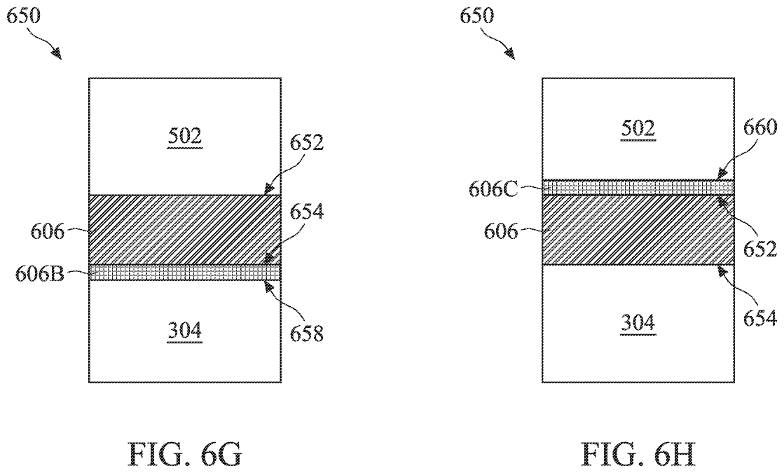

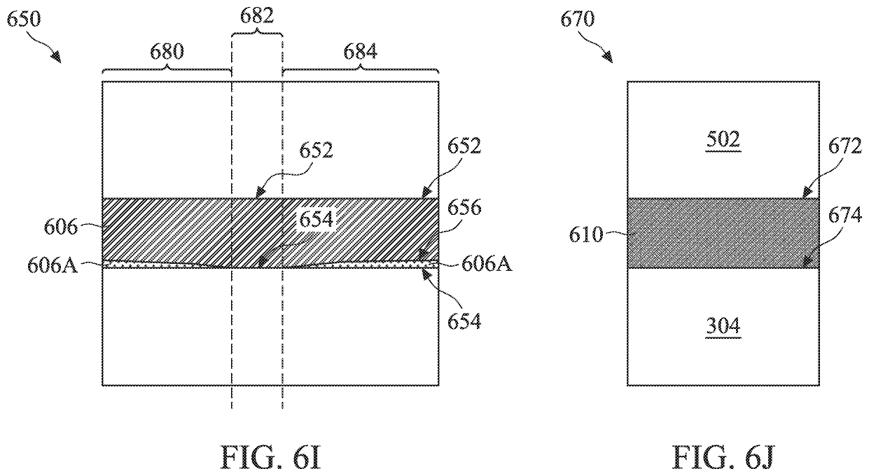

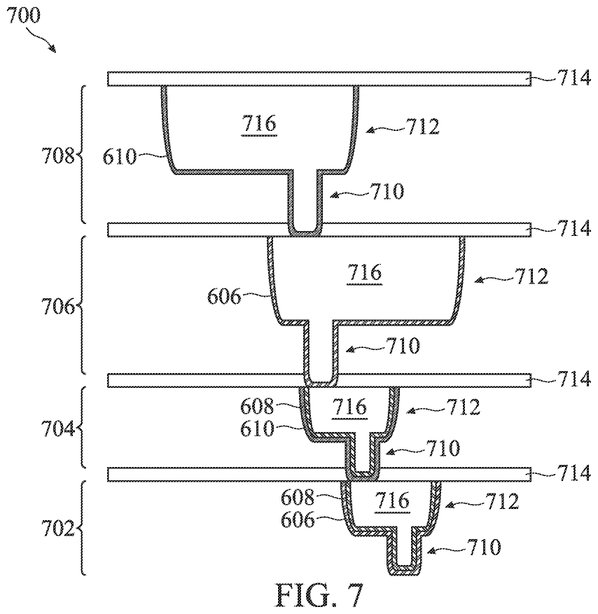

Referring now to FIG. 1, illustrated is a general method 100 of forming an interconnect layer, in accordance with some embodiments. The method 100 is described below in more detail with reference to FIGS. 2-5. Moreover, particular variations to the method 100, based on the particular interconnect structure scheme being implemented, will be described with reference to the method 100 and with reference to FIGS. 6A-6J and FIG. 7, discussed below. It will be understood that additional process steps may be implemented before, during, and after the method 100, and some process steps described may be replaced or eliminated in accordance with various embodiments of the method 100. It will be further understood that parts of the method 100 may be fabricated by a well-known complementary metal-oxide-semiconductor (CMOS) technology process flow, and thus some processes are only briefly described herein.

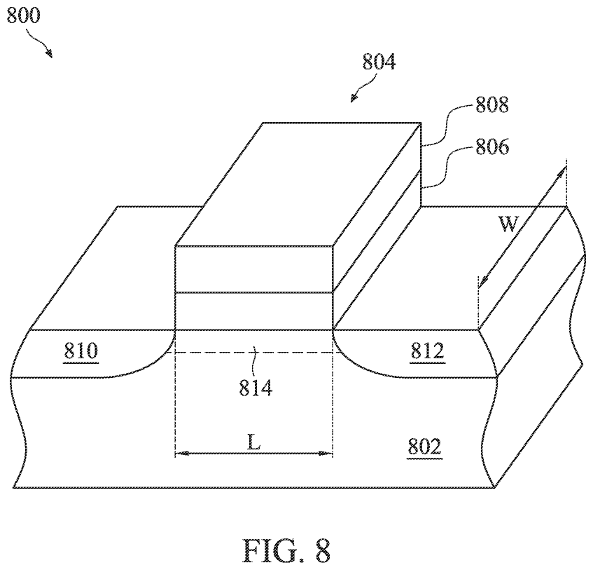

The method 100 begins at block 102 where a substrate including one or more semiconductor devices is provided. With reference to FIG. 2, and in an embodiment of block 102, a device 200 including a substrate 202 is provided, where the substrate 202 includes one or more semiconductor devices. In some embodiments, the substrate 202 and the semiconductor devices therein may include devices such as those described below with reference to FIGS. 8-10. By way of example, the semiconductor devices formed within the substrate 202 may be formed as part of a front-end-of-line (FEOL) process.

The method 100 proceeds to block 104 where a metal layer is formed as part of an interconnect network. Still referring to FIG. 2, and in an embodiment of block 104, a portion of a multi-level metal interconnect network, including a metal layer 204, may be formed over the substrate 202 (e.g., as part of a BEOL process). In some cases, the metal layer 204 may include a portion of a metal line (of the multi-level metal interconnect network) that includes a copper (Cu) layer, an aluminum (Al) layer, an aluminum copper (AlCu) alloy layer, a ruthenium (Ru) layer, a cobalt (Co) layer, or other appropriate metal layer. In other examples, the metal layer 204 may include a portion of a metal via (of the multi-level metal interconnect network) that includes a Cu layer, an Al layer, an AlCu alloy layer, a Ru layer, a Co layer, a tungsten (W) layer, or other appropriate metal layer. In some examples, the metal layer 204 may be deposited by physical vapor deposition (PVD), chemical vapor deposition (CVD), electrochemical plating (ECP), electroless deposition (ELD), ALD, or a combination thereof. In various embodiments, and prior to the deposition of the metal layer 204, additional openings and metal layers (e.g., which may include additional metal lines or metal vias) may be formed beneath the metal layer 204 so as to provide electrical connections between underlying semiconductor devices (e.g., within the substrate 202) and the subsequently deposited metal layer 204.

Moreover, by way of example and prior to forming the metal layer 204, a barrier layer 206 and a liner layer 208 may be formed over the substrate 202. Generally, and in at least some existing implementations, the barrier layer 206 may include TaN, and the liner layer 208 may include Ta, each of which be deposited by CVD, ALD, or PVD. However, in accordance embodiments of the present disclosure, other material compositions and layer configurations are possible. For example, in various embodiments, the barrier layer 206 may include a doped barrier layer or a hybrid barrier layer, and the liner layer 208 is optionally formed over the barrier layer 206. Stated another way, the barrier layer 206/liner layer 208 combination may be formed in accordance with one of the four schemes described herein and including a doped barrier layer with or without a liner layer, and a hybrid barrier layer with or without a liner layer. Additional details regarding the material compositions and layer configurations of the disclosed schemes are provided below with reference to FIGS. 6A-6J.

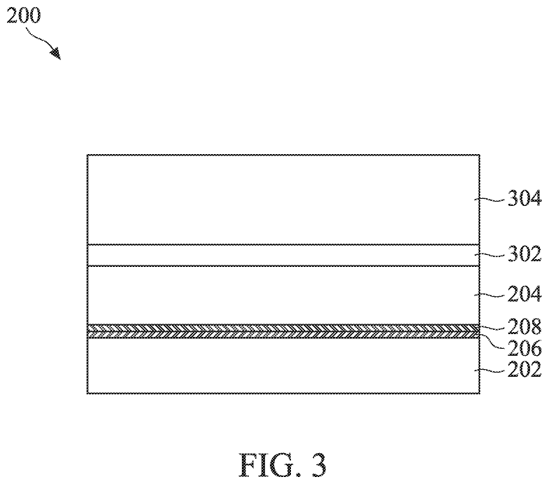

After formation of the metal layer 204, the method 100 proceeds to block 106 where an etch stop layer (ESL) and an inter-layer dielectric (ILD) layer are deposited. With reference to FIGS. 2 and 3, and in an embodiment of block 106, an ESL 302 is deposited over the device 200. The ESL 302 may comprise a single layer or multiple layers. In addition to providing an etch stop, the ESL 302 may also improve etching uniformity. In some embodiments, the ESL 302 may include one or more of AlOx, AlZrOx, ZrOx, SiCN, SiO, SiOC, or other appropriate material. In some cases, the ESL 302 may be deposited by ALD, CVD, PVD, or other appropriate deposition method.

Still referring to FIG. 3, and in a further embodiment of block 106, an ILD layer 304 is deposited over the ESL 302. In some embodiments, the ILD layer 304 may include a dielectric material such as SiCOH, SiOx, or other appropriate material. In some embodiments, ILD layer 304 may alternatively include a low-K dielectric layer such as TEOS oxide, un-doped silicate glass, or doped silicon oxide such as BPSG, FSG, PSG, BSG, and/or other suitable low-K dielectric material. In some cases, ILD layer 304 may be deposited by ALD, CVD, PVD, SACVD, flowable CVD, or other suitable deposition technique. In some cases, after forming the ILD layer 304, a hard mask layer, sacrificial hard mask layer, or combination thereof may be formed over the ILD layer 304.

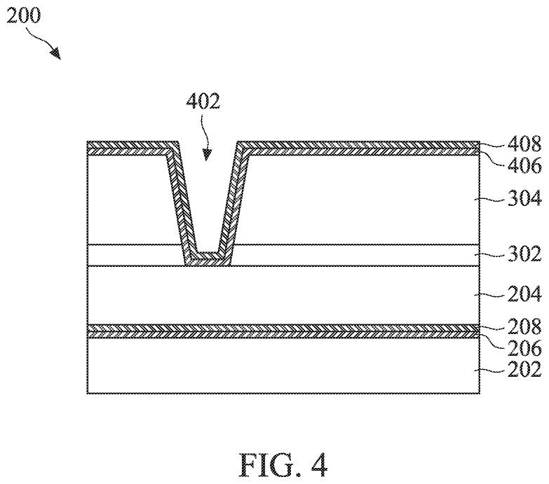

After deposition of the ILD layer 304, the method 100 proceeds to block 108 where the ESL 302 and the ILD layer 304 (and a hard mask layer, if present) are patterned to form a via opening that exposes the metal layer 204. With reference to FIGS. 3 and 4, and in an embodiment of block 108, the ESL 302 and the ILD layer 304 may be patterned using a combination of photolithography (e.g., including photoresist deposition, exposure, and development) and etching (e.g., using a wet or dry etching process) to form a via opening 402 within the ESL 302 and the ILD layer 304. In the example of FIG. 4, the via opening 402 is shown as having a trapezoidal shape. However, in some embodiments, the via opening 402 may have a rectangular shape.

The method 100 proceeds to block 110 where a barrier layer, and optionally a liner layer, is deposited. Still with reference to FIG. 4, and in an embodiment of block 110, a barrier layer 406 and a liner layer 408 are deposited over the device 200 and within the via opening 402, including along sidewalls and a bottom surface of the via opening 402. In various embodiments, the barrier layer 406 and the liner layer 408 are conformally deposited, thus a thickness of the barrier layer 406 and the liner layer 408 may be substantially uniform. Generally, and in at least some existing implementations, the barrier layer 406 may include TaN, and the liner layer 408 may include Ta, each of which be deposited by CVD, ALD, or PVD. However, in accordance embodiments of the present disclosure, other material compositions and layer configurations are possible. For example, in various embodiments, the barrier layer 406 may include a doped barrier layer or a hybrid barrier layer, and the liner layer 408 is optionally formed over the barrier layer 406. Stated another way, the barrier layer 406/liner layer 408 combination may be formed in accordance with one of the four schemes described herein and including a doped barrier layer with or without a liner layer, and a hybrid barrier layer with or without a liner layer. In various cases, the barrier layer 406 and the liner layer 408 may implement a same or different barrier layer/liner layer combination (in accordance with one of the four schemes) as that implemented by the barrier layer 206 and the liner layer 208, discussed above. Further details regarding the material compositions and layer configurations of the disclosed schemes are provided below with reference to FIGS. 6A-6J.

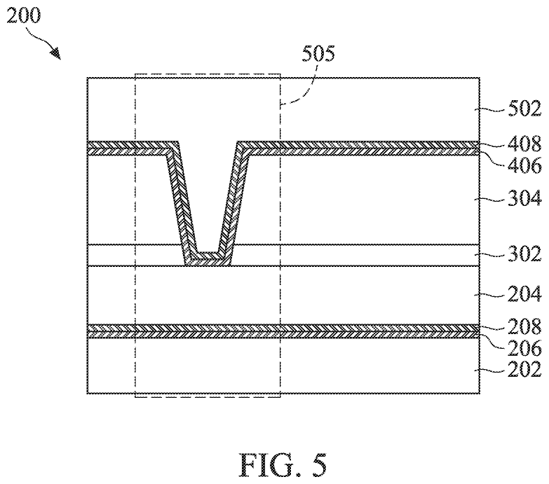

After deposition of the barrier layer 406 (and optional liner layer 408), the method 100 proceeds to block 112 where a metal layer is deposited. With reference to FIGS. 4 and 5, and in an embodiment of block 112, a metal layer 502 is deposited over the barrier layer 406 (or over the liner layer 408, if present) and within the via opening 402. Thus, the metal layer 502 provides electrical contact to the underlying metal layer 204. In some cases, the metal layer 502 may be deposited by ECP, ELD, PVD, ALD, or other appropriate process. In some examples, a seed deposition (e.g., of a Cu seed) may be performed prior to formation of the metal layer 502 (e.g., when the metal layer 502 includes Cu). After formation of the metal layer 502, a chemical mechanical polishing process (CMP) may be performed to remove excess material and to planarize a top surface of the device 200. Thereafter, the method 100 may return to block 106 and repeat blocks 106-112 in order to form each of the interconnect layers of the multi-level metal interconnect network of the device 200.

Referring now to FIGS. 6A-6D, illustrated therein are portions of the device 200 (e.g., see FIG. 5, portion 505) which provide examples of the different interconnect structure schemes that may be implemented as part of the method 100, discussed above. In particular, FIGS. 6A-6D, illustrate embodiments of the various schemes used for implementation of the barrier layers and liner layers in the interconnect structures disclosed herein. For example, FIG. 6A illustrates an embodiment of the device 200 including a doped barrier layer 606 and a liner layer 608, FIG. 6B illustrates an embodiment of the device including the doped barrier layer 606 without the liner layer 608, FIG. 6C illustrates an embodiment of the device 200 including a hybrid barrier layer 610 and the liner layer 608, and FIG. 6D illustrates an embodiment of the device 200 including the hybrid barrier layer 610 without the liner layer 608. In various embodiments, the doped barrier layer 606 and/or the hybrid barrier layer 610 may be used to implement the barrier layer 206 and/or the barrier layer 406, discussed above. Similarly, in some examples, the liner layer 608 may be used to implement the liner layer 208 and/or the liner layer 408, discussed above.

With respect to the embodiment of FIG. 6A, and as part of the method 100, the doped barrier layer 606 is formed, and then the liner layer 608 is formed over the doped barrier layer 606. After formation of the liner layer 608, and in some embodiments, a seed deposition (e.g., of a Cu seed) may be performed prior to formation of the metal layer 502 (e.g., when the metal layer 502 includes Cu). In some cases, the doped barrier layer 606 may be formed by in-situ doping during deposition, or after deposition, of a barrier layer material (e.g., deposited by CVD, ALD, or PVD). Alternatively, the doped barrier layer 606 may be formed by deposition of a barrier layer material (e.g., deposited by CVD, ALD, or PVD) followed by doping via a post treatment process.

In some embodiments, the doped barrier layer 606 may include a Co-based material (e.g., including elemental Co or compound states). By way of example, the Co-based material may include a Co nitride (e.g., CoNₓ, CON, CoₓN), a Co hydride (CoHₓ, CoH), a Co carbide (CoCₓ, CoC, CoₓC), a Co silicide (CoSiₓ, CoSi, CoₓSi), and/or a Co-metal alloy (Co—Ru, Co—Rh, Co—Ir, Co—W, Co—Ti, Co—V, Co—Nb, Co—Ta, Co—Mn, Co—Al, Co—Mg, Co—Zn, Co—Cr, Co—Fe, Co—Ni, Co—Sn, Co—Zr, Co—Mo). In some embodiments, the doped barrier layer 606 may include a Ru-based material (e.g., including elemental Ru or compound states). By way of example, the Ru-based material may include a Ru nitride (RuNₓ, RuN, RuₓN), a Ru hydride (RuHₓ, RuH), a Ru carbide (RuCₓ, RuC, RuₓC), a Ru silicide (RuSiₓ, RuSi, RuₓSi), and/or a Ru-metal alloy (Ru—Co, Ru—Rh, Ru—Ir, Ru—W, Ru—Ti, Ru—V, Ru—Nb, Ru—Ta, Ru—Mn, Ru—Al, Ru—Mg, Ru—Zn, Ru—Cr, Ru—Fe, Ru—Ni, Ru—Sn, Ru—Zr, Ru—Mo). In some embodiments, the doped barrier layer 606 may include a Ta-based material (e.g., including elemental Ta or compound states). By way of example, the Ta-based material may include a Ta nitride (TaNₓ, TaN, TaₓN), a Ta hydride (TaHₓ, TaH), a Ta carbide (TaCₓ, TaC, TaₓC), a Ta silicide (TaSiₓ, TaSi, TaₓSi), and/or a Ta-metal alloy (Ta—Co, Ta—Rh, Ta—Ir, Ta—W, Ta—Ti, Ta—V, Ta—Nb, Ta—Mn, Ta—Al, Ta—Mg, Ta—Zn, Ta—Cr, Ta—Fe, Ta—Ni, Ta—Sn, Ta—Zr, Ta—Mo). In various embodiments, each of the Co-metal alloy, Ru-metal alloy, and the Ta-metal alloy may include alloys with transition metals or inner transition metals.

In some embodiments, one or more of the Co-based materials, Ru-based materials, Ta-based materials, or alloys thereof, provide the doping material(s) that are introduced into a barrier layer to form the doped barrier layer 606. In some embodiments, when the doped barrier layer 606 is formed by in-situ doping, the process may include precursor soaking, with plasma or thermal treatment, during deposition of the doped barrier layer 606 or after deposition of a barrier layer material to thereby form the doped barrier layer 606. By way of example, materials used as precursor gases, carrier gases, and/or gases used to form a plasma during the in-situ doping process may include H₂, N₂, NH₃, H radicals, MeOH, SiH₄, a material with H—, OH—, N—, C—, Si—, O—, and/or CH₃-like and other organic alkyl groups. In some examples, when the doped barrier layer 606 is formed by doping via a post treatment process, the process may include precursor soaking, with plasma or thermal treatment, after deposition of a barrier layer. In various examples, materials used as precursor gases, carrier gases, and/or gases used to form a plasma when doping via a post treatment process may include H₂, N₂, NH₃, H radicals, MeOH, SiH₄, a material with H—, OH—, N—, C—, Si—, O—, CH₃-like and other organic alkyl groups. In some embodiments, when doping via a post treatment process, the dopant material may be introduced into the barrier layer by ALD, CVD, PVD, by an ion implantation process, and/or by a gas soaking process such that the dopant material is embedded within the barrier layer and/or formed on a surface of the barrier layer. While in at least some cases, the doping material(s) may be introduced by in-situ doping during deposition of the doped barrier layer 606, the doped barrier layer 606 may generally be formed by introducing the doping material(s) after formation of a barrier layer material (e.g., either by in-situ doping of a previously deposited barrier layer material or by a post treatment process performed to the previously deposited barrier layer material).

With respect to the embodiment of FIG. 6B, and as part of the method 100, the doped barrier layer 606 is formed, but the liner layer 608 is not formed over the doped barrier layer 606. Instead, after formation of the doped barrier layer 606, and in some embodiments, a seed deposition (e.g., of a Cu seed) may be performed prior to formation of the metal layer 502 (e.g., when the metal layer 502 includes Cu). The doped barrier layer 606 in the embodiment of FIG. 6B may be substantially the same as the doped barrier layer 606 as discussed above with respect to the embodiment of FIG. 6A.

With respect to the embodiment of FIG. 6C, and as part of the method 100, the hybrid barrier layer 610 is formed, and then the liner layer 608 is formed over the hybrid barrier layer 610. After formation of the liner layer 608, and in some embodiments, a seed deposition (e.g., of a Cu seed) may be performed prior to formation of the metal layer 502 (e.g., when the metal layer 502 includes Cu). In some cases, after depositing the hybrid barrier layer 610, and prior to forming the liner layer 608, a post treatment process may be performed to the hybrid barrier layer 610.

In some embodiments, the hybrid barrier layer 610 may include a metal alloy such as a binary metal alloy, a ternary metal alloy, a quaternary metal alloy, or generally a material system including multiple elements. In various cases, the hybrid barrier layer 610 may include Co, Ru, Ta, Nb, Ti, W, Mo, Zn, Al, Mn, Zr, Cr, Fe, Ni, Rh, Ir, a transition metal, a transition metal derivative of carbide/oxide/hydride/nitride/silicide, and/or combinations thereof. In some embodiments, hybrid barrier layer 610 may be formed using a dual-damascene or a single-damascene process. Further, the hybrid barrier layer 610 may be formed using PVD, CVD, ALD, PE-ALD, or PE-CVD. In an example, the hybrid barrier layer 610 may be formed at a temperature in a range from about room temperature (20-25 degrees Celsius) to about 1000 degrees Celsius.

In some examples, after forming the hybrid barrier layer 610, a post treatment process may be performed to the hybrid barrier layer 610. The post treatment process, in some embodiments, includes a plasma soaking or gas treatment using Ar, N₂, NH₃, H₂, or combinations thereof. Alternatively (or additionally), the plasma soaking or gas treatment may be performed using H radicals, MeOH, SiH₄, a material with H—, OH—, N—, C—, Si—, O—, and/or CH₃-like and other organic alkyl groups. In some embodiments, the post treatment process of the hybrid barrier layer 610 may additionally (or alternatively) include bombardment (e.g., using a PVD process) of the hybrid barrier layer 610 with metals, metal alloys, carbides, and/or nitrides.

With respect to the embodiment of FIG. 6D, and as part of the method 100, the hybrid barrier layer 610 is formed, but the liner layer 608 is not formed over the hybrid barrier layer 610. Instead, after formation of the hybrid barrier layer 610, and in some embodiments, a seed deposition (e.g., of a Cu seed) may be performed prior to formation of the metal layer 502 (e.g., when the metal layer 502 includes Cu). The hybrid barrier layer 610 in the embodiment of FIG. 6D may be substantially the same as the hybrid barrier layer 610 as discussed above with respect to the embodiment of FIG. 6C.

In contrast to the doped barrier layer 606, where the doping material(s) (e.g., such as Co-based materials, Ru-based materials, Ta-based materials, or alloys thereof) may generally be introduced after formation of a barrier layer material by one or more sequential processes, the hybrid barrier layer 610 may be formed by simultaneous deposition of the barrier layer material and a doping material(s) (e.g., such as metal alloys, Co, Ru, Ta, Nb, Ti, W, Mo, Zn, Al, Mn, Zr, Cr, Fe, Ni, Rh, Ir, a transition metal, a transition metal derivative of carbide/oxide/hydride/nitride/silicide, and/or combinations thereof) as part of a single process. Due to this difference in the method by which the doping material(s) are introduced into respective ones of the doped barrier layer 606 and the hybrid barrier layer 610, there may be structural differences, including various materials interfaces and/or the presence/absence of elements, that can be detected in the as-fabricated device 200 (e.g., such as by using TEM, SEM, EDS, EDX, or other suitable metrology tool or technique). For example, FIGS. 6E-6I illustrate a portion 650 of the device 200 of FIG. 6B providing different examples for structures than may be formed as part of the doped barrier layer 606, and FIG. 6J illustrates a portion 670 of the device 200 of FIG. 6D, providing an example of the structure that may be formed as part of the hybrid barrier layer 610. Overall, FIGS. 6E-6J are provided to highlight the structural differences that may be present in devices fabricated to include either the doped barrier layer 606 or the hybrid barrier layer 610.

In the example of FIG. 6E, the doped barrier layer 606 is formed over the ILD layer 304, and the metal layer 502 is formed over the doped barrier layer 606 (or over the liner layer 608, if present), as previously discussed. FIG. 6E illustrates a case where there is substantially no intermixing of doping material(s) (introduced into the doped barrier layer 606) with adjacent layers and where the doping material(s) is substantially uniformly distributed throughout a previously deposited barrier layer material, such that a first interface 652 may be defined between the metal layer 502 and the doped barrier layer 606, and a second interface 654 may be defined between the doped barrier layer 606 and the ILD layer 304. FIG. 6F-6I provide variations to the example of FIG. 6E. For example, FIG. 6F illustrates a case where the doping material(s) introduced into the previously deposited barrier layer material does not completely reach a bottom portion of the barrier layer material, such that an undoped barrier layer portion 606A may interpose the doped barrier layer 606 and the underlying ILD layer 304. As a result, the first interface 652 may be defined between the metal layer 502 and the doped barrier layer 606, the second interface 654 may be defined between the undoped barrier layer portion 606A and the ILD layer 304, and a third interface 656 may be defined between the doped barrier layer 606 and the undoped barrier layer portion 606A.

FIG. 6G illustrates a case where the doping material(s) introduced into the previously deposited barrier layer material diffuses into, or otherwise intermixes with, the underlying ILD layer 304, such that a doped ILD layer portion 606B may interpose the doped barrier layer 606 and the underlying ILD layer 304. As a result, the first interface 652 may be defined between the metal layer 502 and the doped barrier layer 606, the second interface 654 may be defined between the doped barrier layer 606 and the doped ILD layer portion 606B, and a third interface 658 may be defined between the doped ILD layer portion 606B and the ILD layer 304.

FIG. 6H illustrates a case where a portion of the doping material(s) that is used to form the doped barrier layer 606 remains disposed on a top surface of the doped barrier layer 606 (as opposed to being incorporated into the previously deposited barrier layer during formation of the doped barrier layer 606), thereby defining a doping material layer 606C. The subsequently formed metal layer 502 may thus be formed over the doping material layer 606C. In cases including the liner layer 608, the liner layer 608 may be formed over the doping material layer 606C, followed by formation of the metal layer 505. Thus, as shown in the present example, the first interface 652 may be defined between the doping material layer 606C and the doped barrier layer 606, the second interface 654 may be defined between the doped barrier layer 606 and the underlying ILD layer 304, and a third interface 660 may be defined between the metal layer 502 and the doping material layer 606C.

It will be understood that the various structural features described above with reference to FIGS. 6E-6H may be present, and detectable, in the as-fabricated device 200. More particularly, it will be understood that more than one of the various structural features, and respective interfaces, may be present in combination with each other in the same device 200, or across different devices 200 on a same substrate (e.g., such as the substrate 202). As merely one illustrative example, reference is made to FIG. 6I, which includes a combination of the cases shown in FIGS. 6E and 6F, discussed above. Specifically, the example of FIG. 6I includes regions 680 and 684 where the undoped barrier layer portion 606A interposes the doped barrier layer 606 and the underlying ILD layer 304. The regions 680, 684 thus include the first interface 652 between the metal layer 502 and the doped barrier layer 606, the second interface 654 between the undoped barrier layer portion 606A and the ILD layer 304, and the third interface 656 between the doped barrier layer 606 and the undoped barrier layer portion 606A. As also shown in the example of FIG. 6I, a region 682 interposes the regions 680, 684, where in the region 682 there is substantially no intermixing of doping material(s) with adjacent layers and the doping material(s) is substantially uniformly distributed throughout the previously deposited barrier layer material within the region 682. The region 682 thus includes the first interface 652 between the metal layer 502 and the doped barrier layer 606, and the second interface 654 between the doped barrier layer 606 and the ILD layer 304.

The example of FIG. 6I thus illustrates a case where the doping material(s) introduced into the previously deposited barrier layer material does not completely reach a bottom portion of the barrier layer material in regions 680, 684, while the doping material(s) is uniformly distributed throughout the barrier layer material within the region 682. While the example of FIG. 6I illustrates one exemplary combination of the various structural features, and respective interfaces, of the embodiments discussed with reference to FIGS. 6E-6H, it will be understood that in other examples, various alternative combinations of the various structural features, and respective interfaces, discussed with reference to FIGS. 6E-6H may be present in the as-fabricated device 200. For instance, while the doping material(s) may largely be largely uniformly distributed throughout doped barrier layer 606, there may be intermittent regions (e.g., similar to the regions 680, 684) including the undoped barrier layer portion 606A, the doped ILD layer portion 606B, or the doping material layer 606C. Such structural features, whether present in intermittent regions or across a device, may help to distinguish devices including the doped barrier layer 606 versus devices including the hybrid barrier layer 610.

In particular, reference is made to the example of FIG. 6J, where the hybrid barrier layer 610 is formed over the ILD layer 304, and the metal layer 502 is formed over the hybrid barrier layer 610 (or over the liner layer 608, if present), as previously discussed. As shown in FIG. 6J, and because the hybrid barrier layer 610 may be formed by simultaneous deposition of the barrier layer material and a doping material(s) as part of a single process, the hybrid barrier layer 610 includes a material composition that is substantially uniform, thereby providing substantially clean and uniform interfaces with adjacent material layers. As such, the example of FIG. 6J includes that a first interface 672 that may be defined between the metal layer 502 and the hybrid barrier layer 610, and a second interface 674 that may be defined between the hybrid barrier layer 610 and the ILD layer 304.

The consistently clean and uniform interfaces provided by implementation of the hybrid barrier layer 610 may generally contrast the structural features, and respective interfaces, present in devices implementing the doped barrier layer 606. As noted above, this may help to distinguish devices including the doped barrier layer 606 versus devices including the hybrid barrier layer 610. It will also be understood that the single process of forming the hybrid barrier layer 610 may generally be less complex than the sequential processes used to form the doped barrier layer 606. For example, the sequential processes used to form the doped barrier layer 606 may employ plural processing chambers of a multi-chamber processing system, while the single process used to form the hybrid barrier layer 610 may employ a single, multi-function chamber capable of simultaneous deposition of the barrier layer material and the doping material(s).

With reference now to FIG. 7, illustrated therein is an exemplary portion of a multi-level metal interconnect network 700 of the device 200 that may be formed in accordance with the method 100, discussed above. As shown, the multi-level interconnect network 700 includes a plurality of interconnect levels 702, 704, 706, 708. As shown, each of the plurality of interconnect levels 702, 704, 706, 708 includes a via portion 710 and a metal line portion 712. In some embodiments, the via portion 710 and the metal line portion 712 include a metal layer 716, which may be similar to the metal layers 204, 502, previously discussed. The plurality of interconnect levels 702, 704, 706, 708 may include any of the metallization levels formed over the substrate 202 of the device 200, for example, as part of a BEOL process. An etch stop layer (ESL) 714, which may be similar to the previously discussed ESL 302, is also shown as interposing adjacent ones of the plurality of interconnect levels 702, 704, 706, 708. It will be understood that a surrounding dielectric layer, such as the previously discussed ILD layer 304, is also provided surrounding the via portion 710 and the metal line portion 712 of each of the plurality of interconnect levels 702, 704, 706, 708.

In accordance with the embodiments disclosed herein, each of the plurality of interconnect levels 702, 704, 706, 708 of the multi-level metal interconnect network 700 may be formed using any of the various schemes, such as discussed above with reference to FIGS. 6A-6D, for implementation of the barrier layers and liner layers in respective ones of the plurality of interconnect levels 702, 704, 706, 708. In the illustrated example, the interconnect level 702 includes the doped barrier layer 606 and the liner layer 608 (e.g., see FIG. 6A) interposing the via portion 710/metal line portion 712 and the surrounding dielectric layer, the interconnect level 704 includes the hybrid barrier layer 610 and the liner layer 608 (e.g., see FIG. 6C) interposing the via portion 710/metal line portion 712 and the surrounding dielectric layer, the interconnect level 706 includes the doped barrier layer 606 without the liner layer 608 (e.g., see FIG. 6B) interposing the via portion 710/metal line portion 712 and the surrounding dielectric layer, and the interconnect level 708 includes the hybrid barrier layer 610 without the liner layer 608 (e.g., see FIG. 6D) interposing the via portion 710/metal line portion 712 and the surrounding dielectric layer. While the example of FIG. 7 illustrates a particular configuration of the barrier layers and liner layers in respective ones of the plurality of interconnect levels 702, 704, 706, 708, the example provided is not meant to be limiting, and in other embodiments, different configurations may be used without departing from the scope of the present disclosure. In particular, and in various embodiments, any of the various schemes for implementation of the barrier layers and liner layers (e.g., as shown in FIGS. 6A-6D) may be implemented within each of the plurality of interconnect levels 702, 704, 706, 708. Stated another way, each of the interconnect levels 702, 704, 706, 708 may include any of the four schemes (e.g., which may also be referred to a barrier layer configurations) described herein: (i) a doped barrier layer with a liner layer; (ii) a doped barrier layer without a liner layer; (iii) a hybrid barrier layer with a liner layer; or (iv) a hybrid barrier layer without a liner layer.

As previously noted, implementation of the hybrid barrier layer 610 may provide cleaner and more uniform interfaces as compared to implementations of the doped barrier layer 606. Thus, in some examples, it may be desirable to use the hybrid barrier layer 610 in the more critical lower metal layers of the BEOL interconnect structure (e.g., such as in metal layers M0-M3, where a metal line pitch is less than or equal to about 40 nm), while either the hybrid barrier layer 610 or the doped barrier layer 606 may be used in higher metal layers of the BEOL interconnect structure (e.g., such as in metal layers M4 or higher, where a metal line pitch is greater than about 40 nm). To be sure, in some examples, the doped barrier layer 606 may alternatively be used in the lower metal layers as well. With respect to the liner layer 608, use of the liner layer 608 provides for better gap filling, which in turn can provide better device yield. In some examples, the liner layer 608 may thus generally be employed within the lower metal layers of the BEOL interconnect structure (e.g., such as in metal layers M0-M3) where the metal line pitch is reduced and where gap filling would be more challenging without the liner layer 608. In higher metal layers of the BEOL interconnect structure (e.g., such as in metal layers M4 or higher) where the metal line pitch is increased, gap filling may not be as much of an issue, and thus the liner layer 608 may not be needed (although it may still be used, in some implementations). It should also be noted that the liner layer 608 can also negatively impact resistivity of the metal layer, in some cases. Thus, the decision of whether to use the liner layer 608 also depends on device performance requirements. Overall, the decision of which of the four schemes to implement (e.g., doped barrier layer with or without a liner layer, and hybrid barrier layer with/without a liner layer) may depend on consideration of a combination of device performance and yield requirements for each of the given metal layers of the BEOL interconnect structure.

As discussed above, the semiconductor devices formed within the substrate 202 may include devices such as those described with reference to FIGS. 8-10. In addition, while the above discussion presented embodiments for forming a barrier layer and/or a liner layer within a BEOL process, the techniques described herein may be employed to form barrier and/or liner layers formed as part of the fabrication of devices in a FEOL process, such as those described with reference to FIGS. 8-10. As such, the devices of FIGS. 8-10 will now be discussed.

Referring first to the example of FIG. 8, illustrated therein is an MOS transistor 800, providing an example of merely one device type which may include embodiments of the present disclosure. The transistor 800 is fabricated on a substrate 802 and includes a gate stack 804. The substrate 802 may be a semiconductor substrate such as a silicon substrate. The substrate 802 may include various layers, including conductive or insulating layers formed on the substrate 802. The substrate 802 may include various doping configurations depending on design requirements as is known in the art. The substrate 802 may also include other semiconductors such as germanium, silicon carbide (SiC), silicon germanium (SiGe), or diamond. Alternatively, the substrate 802 may include a compound semiconductor and/or an alloy semiconductor. Further, in some embodiments, the substrate 802 may include an epitaxial layer (epi-layer), the substrate 802 may be strained for performance enhancement, the substrate 802 may include a silicon-on-insulator (SOI) structure, and/or the substrate 802 may have other suitable enhancement features.

The gate stack 804 includes a gate dielectric 806 and a gate electrode 808 disposed on the gate dielectric 806. In some embodiments, the gate dielectric 806 may include an interfacial layer such as silicon oxide layer (SiO₂) or silicon oxynitride (SiON), where such interfacial layer may be formed by chemical oxidation, thermal oxidation, ALD, CVD, and/or other suitable method. In some examples, the gate dielectric 806 includes a high-k dielectric layer such as hafnium oxide (HfO₂). Alternatively, the high-k dielectric layer may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. High-K gate dielectrics, as used and described herein, include dielectric materials having a high dielectric constant, for example, greater than that of thermal silicon oxide (˜3.9). In still other embodiments, the gate dielectric 806 may include silicon dioxide or other suitable dielectric. The gate dielectric 806 may be formed by ALD, PVD, CVD, oxidation, and/or other suitable methods.

In some embodiments, the gate electrode 808 may be deposited as part of a gate first or gate last (e.g., replacement gate) process. In various embodiments, the gate electrode 808 includes a conductive layer such as W, Ti, TiN, TiAl, TiAlN, Ta, TaN, WN, Re, Ir, Ru, Mo, Al, Cu, Co, CoSi, Ni, NiSi, combinations thereof, and/or other suitable compositions. In some examples, the gate electrode 808 may include a first metal material for an N-type transistor and a second metal material for a P-type transistor. Thus, the transistor 800 may include a dual work-function metal gate configuration. For example, the first metal material (e.g., for N-type devices) may include metals having a work function substantially aligned with a work function of the substrate conduction band, or at least substantially aligned with a work function of the conduction band of a channel region 814 of the transistor 800. Similarly, the second metal material (e.g., for P-type devices) may include metals having a work function substantially aligned with a work function of the substrate valence band, or at least substantially aligned with a work function of the valence band of the channel region 814 of the transistor 800. Thus, the gate stack 804 may provide a gate electrode for the transistor 800, including both N-type and P-type devices. In some embodiments, the gate electrode 808 may alternately or additionally include a polysilicon layer. In various examples, the gate electrode 808 may be formed using PVD, CVD, electron beam (e-beam) evaporation, and/or other suitable process. In some embodiments, sidewall spacers are formed on sidewalls of the gate stack 804. Such sidewall spacers may include a dielectric material such as silicon oxide, silicon nitride, silicon carbide, silicon oxynitride, or combinations thereof.

The transistor 800 further includes a source region 810 and a drain region 812 each formed within the semiconductor substrate 802, adjacent to and on either side of the gate stack 804. In some embodiments, the source and drain regions 810, 812 include diffused source/drain regions, ion implanted source/drain regions, epitaxially grown regions, or a combination thereof. The channel region 814 of the transistor 800 is defined as the region between the source and drain regions 810, 812 under the gate dielectric 806, and within the semiconductor substrate 802. The channel region 814 has an associated channel length “L” and an associated channel width “W”. When a bias voltage greater than a threshold voltage (Vt) (i.e., turn-on voltage) for the transistor 800 is applied to the gate electrode 808 along with a concurrently applied bias voltage between the source and drain regions 810, 812, an electric current (e.g., a transistor drive current) flows between the source and drain regions 810, 812 through the channel region 814. The amount of drive current developed for a given bias voltage (e.g., applied to the gate electrode 808 or between the source and drain regions 810, 812) is a function of, among others, the mobility of the material used to form the channel region 814. In some examples, the channel region 814 includes silicon (Si) and/or a high-mobility material such as germanium, which may be epitaxially grown, as well as any of the plurality of compound semiconductors or alloy semiconductors as known in the art. High-mobility materials include those materials with electron and/or hole mobility greater than silicon (Si), which has an intrinsic electron mobility at room temperature (300 K) of around 1350 cm²/V-s and an intrinsic hole mobility at room temperature (300 K) of around 480 cm²/V-s.

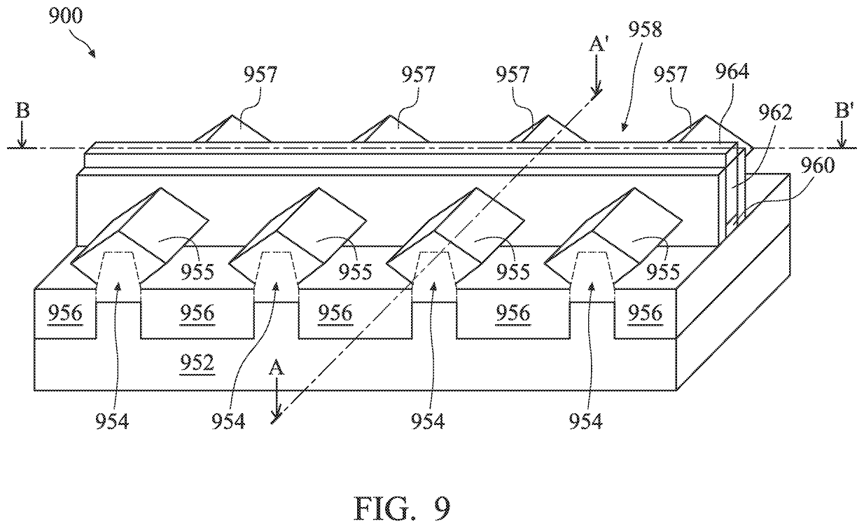

Referring now to FIG. 9, illustrated therein is a FinFET device 900, providing an example of an alternative device type which may include embodiments of the present disclosure. By way of example, the FinFET device 900 includes one or more fin-based, multi-gate field-effect transistors (FETs). The FinFET device 900 includes a substrate 952, at least one fin element 954 extending from the substrate 952, isolation regions 956, and a gate structure 958 disposed on and around the fin element 954. The substrate 952 may be a semiconductor substrate such as a silicon substrate. In various embodiments, the substrate 952 may be substantially the same as the substrate 802 and may include one or more of the materials used for the substrate 802, as described above.

The fin element 954, like the substrate 952, may include one or more epitaxially-grown layers, and may comprise silicon or another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlInAs, AlGaAs, InGaAs, GaInP, and/or GaInAsP; or combinations thereof. The fins 954 may be fabricated using suitable processes including photolithography and etch processes. The photolithography process may include forming a photoresist layer (resist) overlying the substrate (e.g., on a silicon layer), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate while an etch process forms recesses into the silicon layer, thereby leaving an extending fin 954. The recesses may be etched using a dry etch (e.g., chemical oxide removal), a wet etch, and/or other suitable processes. Numerous other embodiments of methods to form the fins 954 on the substrate 952 may also be used.

Each of the plurality of fins 954 also include a source region 955 and a drain region 957 where the source/drain regions 955, 957 are formed in, on, and/or surrounding the fin 954. The source/drain regions 955, 957 may be epitaxially grown over the fins 954. In addition, a channel region of a transistor is disposed within the fin 954, underlying the gate structure 958, along a plane substantially parallel to a plane defined by section AA′ of FIG. 9. In some examples, the channel region of the fin includes a high-mobility material, as described above.

The isolation regions 956 may be shallow trench isolation (STI) features. Alternatively, a field oxide, a LOCOS feature, and/or other suitable isolation features may be implemented on and/or within the substrate 952. The isolation regions 956 may be composed of silicon oxide, silicon nitride, silicon oxynitride, FSG, a low-k dielectric, combinations thereof, and/or other suitable material known in the art. In an embodiment, the isolation regions 956 are STI features and are formed by etching trenches in the substrate 952. The trenches may then be filled with isolating material, followed by a CMP process. However, other embodiments are possible. In some embodiments, the isolation regions 956 may include a multi-layer structure, for example, having one or more liner layers.

The gate structure 958 includes a gate stack having an interfacial layer 960 formed over the channel region of the fin 954, a gate dielectric layer 962 formed over the interfacial layer 960, and a metal layer 964 formed over the gate dielectric layer 962. In various embodiments, the interfacial layer 960 is substantially the same as the interfacial layer described as part of the gate dielectric 806. In some embodiments, the gate dielectric layer 962 is substantially the same as the gate dielectric 806 and may include high-k dielectrics similar to that used for the gate dielectric 806. Similarly, in various embodiments, the metal layer 964 is substantially the same as the gate electrode 808, described above. In some embodiments, sidewall spacers are formed on sidewalls of the gate structure 958. The sidewall spacers may include a dielectric material such as silicon oxide, silicon nitride, silicon carbide, silicon oxynitride, or combinations thereof.

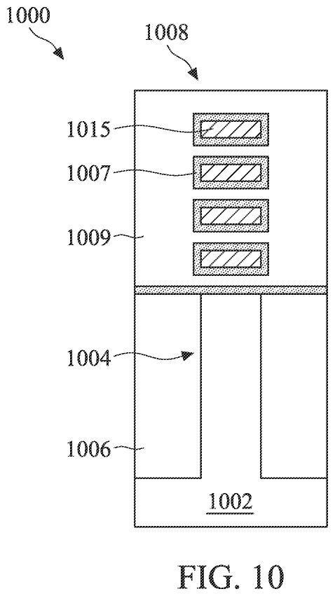

Referring to FIG. 10, illustrated therein is a GAA device 1000, providing an example of another device type which may include embodiments of the present disclosure. By way of example, the GAA device 1000 includes one or more fin-based, multi-gate FETs. As the overall structure of the GAA device 1000 is similar in many respects to the FinFET device 900 of FIG. 9, the GAA device 1000 of FIG. 10 may be described as providing an exemplary cross-section of the GAA device 1000 along a plane substantially parallel to a plane defined by section BB′ of FIG. 9. The GAA device 1000 includes a substrate 1002, fins 1004, isolation regions 1006 (e.g., such as STI regions), and a gate stack 1008, which may be similar to those described above. In some embodiments, the fins 1004 include a plurality of semiconductor channel layers 1015 (e.g., such as epitaxial Si nanosheet layers) that are interposed by portions of the gate stack 1008. In addition, the gate stack 1008 includes a gate dielectric layer 1007 (e.g., including an interfacial layer and a high-K gate dielectric layer) surrounding each of the plurality of semiconductor channel layers 1015, and a gate electrode 1009 formed over the gate dielectric layer 1007. In various embodiments, the gate dielectric layer 1007 and the gate electrode 1009 are similar to those described above.

As discussed above, each of the transistor 800, the FinFET device 900, and the GAA device 1000 may include barrier layers and/or liner layers formed as described above. For instance, each of the transistor 800, the FinFET device 900, and the GAA device 1000 may include (i) a doped barrier layer with a liner layer; (ii) a doped barrier layer without a liner layer; (iii) a hybrid barrier layer with a liner layer; and/or (iv) a hybrid barrier layer without a liner layer.

The various embodiments described herein thus offer several advantages over the existing art. It will be understood that not all advantages have been necessarily discussed herein, no particular advantage is required for all embodiments, and other embodiments may offer different advantages. As one example, embodiments discussed herein include an interconnect structure, and related methods, that effectively serve to overcome various shortcomings of existing methods. In particular, a variety of schemes are provided for implementation of the barrier layer and/or liner layer to effectively reduce the resistance of the interconnect structure, including reducing the resistance of the metal interconnect layer. For instance, the barrier layer may include a doped barrier layer, where an in-situ treatment process and/or a post-treatment process may be performed. A liner layer may optionally be formed over the doped barrier layer prior to formation of a metal interconnect layer. Alternatively, in some embodiments, the interconnect structure may include a hybrid barrier layer, and a post treatment process may be optionally performed. A liner layer may optionally be formed over the hybrid barrier layer prior to formation of a metal interconnect layer. Thus, in general and with respect to implementation of the barrier layers and liner layers in the interconnect structures disclosed herein, at least four different schemes are provided: (i) doped barrier layer with a liner layer; (ii) doped barrier layer without a liner layer; (iii) hybrid barrier layer with a liner layer; and (iv) hybrid barrier layer without a liner layer. Regardless of the particular implementation (or scheme), embodiments of the present disclosure provide for reduced resistance of the interconnect structure. Additional benefits and/or other advantages will become apparent to those skilled in the art having benefit of the present disclosure.

Thus, one of the embodiments of the present disclosure described a method for fabricating a semiconductor device including forming a first metal interconnect layer, depositing a dielectric layer over the first metal interconnect layer, patterning the dielectric layer to form an opening that exposes the first metal interconnect layer, forming a doped barrier layer or a hybrid barrier layer along sidewalls and a bottom surface of the opening, and depositing a metal layer over the doped barrier layer or the hybrid barrier layer.

In another of the embodiments, discussed is a method of fabricating a semiconductor device including forming a first level of a multi-level interconnect network. In some embodiments, the first level of the multi-level interconnect network includes a first via portion and a first metal line portion. In some examples, the method further includes forming a second level of the multi-level interconnect network over the first level of the multi-level interconnect network. In some embodiments, the second level of the multi-level interconnect network includes a second via portion and a second metal line portion. In various examples, the first level of the multi-level interconnect network includes a first barrier layer configuration at least partially surrounding the first via portion and the first metal line portion. In some embodiments, the second level of the multi-level interconnect network includes a second barrier layer configuration, different than the first barrier layer configuration, at least partially surrounding the second via portion and the second metal line portion.

In yet another of the embodiments, discussed is a device including a substrate having one or more semiconductor devices, a first level of a multi-level interconnect network formed over the substrate, and a second level of the multi-level interconnect network formed over the first level of the multi-level interconnect network. In some embodiments, the first level of the multi-level interconnect network includes a first barrier layer at least partially surrounding a first metal layer of the first level of the multi-level interconnect network. In some examples, the second level of the multi-level interconnect network includes a second barrier layer, different than the first barrier layer, at least partially surrounding a second metal layer of the second level of the multi-level interconnect network.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
forming a first metal interconnect layer;
depositing a dielectric layer over the first metal interconnect layer;
patterning the dielectric layer to form an opening that exposes the first metal interconnect layer;
forming a doped barrier layer or a hybrid barrier layer along sidewalls and a bottom surface of the opening; and
depositing a metal layer over the doped barrier layer or the hybrid barrier layer.

2. The method of claim 1, further comprising:
prior to depositing the metal layer, forming a liner layer over the doped barrier layer or the hybrid barrier layer; and
depositing the metal layer over the liner layer.

3. The method of claim 1, wherein the forming the doped barrier layer or the hybrid barrier layer includes forming the doped barrier layer along the sidewalls and the bottom surface of the opening.

4. The method of claim 1, wherein the forming the doped barrier layer or the hybrid barrier layer includes forming the hybrid barrier layer along the sidewalls and the bottom surface of the opening.

5. The method of claim 3, wherein the doped barrier layer includes a Co nitride, a Co hydride, a Co carbide, a Co silicide, or a Co metal alloy.

6. The method of claim 3, wherein the doped barrier layer includes a Ru nitride, a Ru hydride, a Ru carbide, a Ru silicide, or a Ru metal alloy.

7. The method of claim 3, wherein the doped barrier layer includes a Ta nitride, a Ta hydride, a Ta carbide, a Ta silicide, or a Ta metal alloy.

8. The method of claim 3, wherein the doped barrier layer is formed by in-situ doping using precursor soaking, with plasma or thermal treatment, during or after the formation of the doped barrier layer.

9. The method of claim 3, wherein the doped barrier layer is formed by doping via a post treatment process using precursor soaking, with plasma or thermal treatment, after the formation of a barrier layer used to form the doped barrier layer.

10. The method of claim 4, wherein after forming the hybrid barrier layer, performing a bombardment of the hybrid barrier layer using metals, metal alloys, carbides, or nitrides.

11. A method of fabricating a semiconductor device, comprising:
forming a first level of a multi-level interconnect network, wherein the first level of the multi-level interconnect network includes a first via portion and a first metal line portion; and
forming a second level of the multi-level interconnect network over the first level of the multi-level interconnect network, wherein the second level of the multi-level interconnect network includes a second via portion and a second metal line portion;
wherein the first level of the multi-level interconnect network includes a first barrier layer configuration at least partially surrounding the first via portion and the first metal line portion; and
wherein the second level of the multi-level interconnect network includes a second barrier layer configuration, different than the first barrier layer configuration, at least partially surrounding the second via portion and the second metal line portion.

12. The method of claim 11, wherein the first barrier layer configuration includes one of: (i) a doped barrier layer and a liner layer disposed over the doped barrier layer; (ii) the doped barrier layer without the liner layer; (iii) a hybrid barrier layer and the liner layer disposed over the hybrid barrier layer; and (iv) the hybrid barrier layer without the liner layer.

13. The method of claim 12, wherein the second barrier layer configuration includes a different one of: (i) the doped barrier layer and the liner layer disposed over the doped barrier layer;
(ii) the doped barrier layer without the liner layer; (iii) the hybrid barrier layer and the liner layer disposed over the hybrid barrier layer; and (iv) the hybrid barrier layer without the liner layer.

14. The method of claim 12, wherein the doped barrier layer includes a Co nitride, a Co hydride, a Co carbide, a Co silicide, or a Co metal alloy.

15. The method of claim 12, wherein the doped barrier layer includes a Ru nitride, a Ru hydride, a Ru carbide, a Ru silicide, or a Ru metal alloy.

16. The method of claim 12, wherein the doped barrier layer includes a Ta nitride, a Ta hydride, a Ta carbide, a Ta silicide, or a Ta metal alloy.

17. The method of claim 12, wherein the hybrid barrier layer includes a barrier layer bombarded with metals, metal alloys, carbides, or nitrides.

18. A device, comprising:
a substrate including one or more semiconductor devices;
a first level of a multi-level interconnect network formed over the substrate; and
a second level of the multi-level interconnect network formed over the first level of the multi-level interconnect network;
wherein the first level of the multi-level interconnect network includes a first barrier layer at least partially surrounding a first metal layer of the first level of the multi-level interconnect network; and
wherein the second level of the multi-level interconnect network includes a second barrier layer, different than the first barrier layer, at least partially surrounding a second metal layer of the second level of the multi-level interconnect network.

19. The device of claim 18, wherein the first barrier layer includes one of a doped barrier layer and a hybrid barrier layer, and wherein the second barrier layer includes a different one of the doped barrier layer and the hybrid barrier layer.

20. The device of claim 18, further comprising at least one of a first liner layer interposing the first barrier layer and the first metal layer and a second liner layer interposing the second barrier layer and the second metal layer.
